(19) United States
(12) Patent Application Publication
(10) Pub. No.: US 2009/0159869 A1
(43) Pub. Date: Jun. 25, 2009

(54) Solid State Light Emitting Device

(76) Inventors: Fernando A. Ponce, Tempe, AZ (US); Sridhar Srinivasan, Bangalore (IN); Hiromasa Omiya, Tokushima-Ken (JP)

Correspondence Address: Greg L. Martinez, 3116 South Mill Ave. #408, Tempe, AZ, 85282, US

(21) Appl. No.: 11/886,027

(22) PCT Filed: Mar. 10, 2006
(86) PCT No.: PCT/US06/08735

§ 371 Date: Aug. 14, 2008

Related U.S. Application Data
(60) Provisional application No. 60/661,166, filed on Mar. 11, 2005.
(60) Provisional application No. 60/661,251, filed on Mar. 11, 2005.

(51) Int. Cl. H01L 33/00; H01L 21/18

(52) U.S. Cl. 257/13; 257/94; 438/47; 257/E33.027; 257/E33.008; 257/E21.089

(57) ABSTRACT

A semiconductor structure (10, 10′, 70, 80) includes a light emitter (12, 72) carried by a support structure (11). The light emitter (12, 72) includes a base region (24, 76) with a sloped sidewall (12a, 12b) and a light emitting region (25, 77) positioned thereon. The light emitting (25, 77) region includes a nitride semiconductor alloy having a composition that is different in a first region (26, 95) near the support structure (11) compared to a second region (27, 96) away from the support structure (11).

### CROSS-REFERENCE TO RELATED APPLICATIONS

This application claims benefit to U.S. Provisional Applications Ser. Nos. 60/661,166 and 60/661,251, which were both filed on Mar. 11, 2005 and are incorporated herein by reference.

### BACKGROUND OF THE INVENTION

1. Field of the Invention

This invention relates generally to semiconductor devices and, more particularly, to semiconductor devices which emit light.

2. Description of the Related Art

Indium gallium nitride (InGaN) alloys are important nitride materials for applications in solid state light emitting devices, such as light emitting diodes (LEDs) and laser diodes (LDs). The bandgap of these alloys can be changed from less than 1 electron volt (eV) to 3.4 eV by varying their composition. Hence, light emitting devices that include InGaN alloys in their active regions can emit light in the visible, ultraviolet (UV), and infrared (IR) regions of the electromagnetic spectrum.

Many of these InGaN-based devices have been commercialized by companies such as Lumileds, Inc. and Nichia Corp. and are described in many different U.S. Patents. For example, U.S. Pat. No. 6,153,010 by Kiyoku, et al. discloses a method of growing nitride semiconductors, a nitride semiconductor substrate, and a nitride semiconductor device. U.S. Pat. No. 5,959,307 by Nakamura, et al. discloses a nitride semiconductor device and U.S. Pat. No. 5,563,422 by Nakamura, et al. discloses a gallium nitride-based III-V group compound semiconductor device and a method of producing the same.

An important application of InGaN-based devices is in the fabrication of LEDs and LDs which emit light in the green to red regions of the visible light spectrum. However, the difficulty in growing device quality InGaN material with a large enough amount of indium (In) has inhibited the potential of these devices to emit green and longer wavelength light. Device quality material generally has fewer defects, such as impurities and dislocations, than lower quality material. Hence, electrical devices that include device quality material typically operate better than those with lower quality material. The composition of the indium gallium nitride alloy is often written as InₓGa₁₋ₓN, where x is the fraction of indium included therein. A large amount of indium corresponds to a value of x equal to about 0.15 (i.e. 15%) or greater.

There are several problems associated with the growth of InGaN with a large amount of indium. One problem is the weak strength of the indium-nitrogen (In—N) bond. Since the In—N bond is weak, it must be formed at a low growth temperature. Ammonia (NH₃) is generally used as the nitrogen source gas when growing nitride materials, but at low growth temperatures, it is more difficult to dissociate ammonia to provide nitrogen. This makes it more difficult to incorporate nitrogen into the InGaN alloy.

Another problem is that there is a large lattice mismatch between InGaN and gallium nitride (GaN), which is another nitride material often included in InGaN-based devices. During the last few years several groups have tried to grow InGaN films with a fractional amount of indium greater than about 0.15 (i.e. 15%). However, the lattice mismatch between InGaN and GaN can be up to about 11%, which makes InGaN/GaN heterostructures highly strained. Further, InGaN alloys are known to be thermodynamically unstable with these amounts of indium and, as a result, are known to undergo phase separation. Hence, these attempts have provided InGaN films that are not device quality.

Another important application of InGaN-based devices is in the fabrication of light emitters that emit white light. These light emitters have the potential to replace conventional lighting sources because of their superior efficiency and longevity.

There are several ways to make light emitting devices that emit white light. One way is based on the color mixing of the three primary colors, red, green, and blue (RGB). In this approach, three separate red, green, and blue LEDs are biased independently and their light output is combined in specific proportions to produce white light. However, this design approach is difficult to utilize in mass production. One reason for this is because of the difficulty in mounting the three separate LEDs in one package and providing external contacts to them.

Another way of making light emitting devices that emit white light is based on the down conversion of light from short to long wavelengths. In this approach, a short-wavelength LED is coated with an appropriate phosphor. The short-wavelength LED emits UV or blue light which is down converted by the phosphor to a broader spectrum of longer wavelengths, such as green, yellow, red, etc. The combination of these colors of light has the effect of providing white light. For example, a blue LED coated with a yellow phosphor produces white light.

Although this is currently the preferred method for generating white light, it suffers from several disadvantages. For example, the mixing of blue and yellow light has little or no red component, so there is poor red color rendering capability. Further, light conversion using this approach results in undesirable down conversion losses, which decreases the efficiency of the device. Accordingly, there is a need for a solid state light emitting device that can emit light in a wider range of light spectrums and provide longer wavelengths of light.

### BRIEF SUMMARY OF THE INVENTION

The present invention provides several semiconductor structures, which can operate as solid state light emitting devices, and several methods of operating and fabricating them. The semiconductor structure includes a light emitter carried by a support structure. The light emitter includes a base region with a sloped sidewall and a light emitting region carried thereon. The light emitting region includes a nitride semiconductor alloy having a composition that is different in a first region near the support structure compared to a second region away from the support structure. The light emitting region emits various colors of light in response to a potential difference provided to the light emitter. In this way, the light emitting region operates as an active region. The colors can include longer wavelengths of light, such as green, yellow, and red, as well as shorter wavelengths of light, such as blue and violet. These colors can also be combined with each other to provide various combinations of colors, including white light.

These and other features, aspects, and advantages of the present invention will become better understood with reference to the following drawings, description, and claims.

### BRIEF DESCRIPTION OF THE DRAWINGS

FIGS. 1a and 1b are perspective and top views, respectively, of a semiconductor structure, in accordance with the present invention, with a triangular prism shape;

FIGS. 2a-2e are side views showing steps in the fabrication of the semiconductor structure of FIG. 1a, in accordance with the present invention;

FIGS. 2f-2g are side views showing steps in the fabrication of an alternative embodiment of the semiconductor structure of FIG. 1a, in accordance with the present invention;

FIG. 3a is a graph of the cathodoluminescence (CL) spectrum of a light emitting region included in the structure of FIG. 1a;

FIG. 3b is a sectional view of the structure of FIG. 1a and corresponding images from a top view showing the emission of light at different wavelengths from different portions of the structure;

FIG. 4a is a graph showing CL peak positions in electron-volts (eV) versus growth temperature in ° C. for the light emitting region of FIG. 1a;

FIG. 4b is a graph showing the fractional indium composition (x) versus the growth temperature in ° C. for the light emitting region included in the structure of FIG. 1a;

FIG. 5a is a graph showing the CL intensity versus energy in electron-volts (eV) for different light emitting regions included in the structure of FIG. 1a;

FIG. 5b is a graph showing the CL spectrum versus energy in electron volts for an InGaN sample having a planar geometry which occupies a cubic volume of InGaN material;

FIGS. 6a and 6b are perspective and top views, respectively, of a semiconductor structure, in accordance with the present invention, having a triangular prism shape;

FIG. 7a is a graph showing the CL spectrum versus the wavelength in nanometers (nm) for the structure of FIG. 6a;

FIG. 7b is a sectional view of the semiconductor structure of FIG. 6a and corresponding images from a top view showing the emission of light at different wavelengths from different portions of the structure;

FIG. 8a is a graph of the wavelength of light emitted from the light emitting region of the structure of FIG. 6a versus a distance along the region for different growth conditions;

FIG. 8b is a graph showing the CL intensity versus wavelength in nanometers (nm) for the spectrum corresponding to the light emitted from the structure of FIG. 6a in comparison with the solar spectrum and human eye response;

FIGS. 9a, 9b, and 9c show perspective, top, and side views, respectively, of a semiconductor structure, in accordance with the present invention, with a triangular prism shape that can emit various combinations of light separately or in combination;

FIGS. 10a and 10b are perspective and top views, respectively, of a semiconductor structure, in accordance with the present invention, with a pyramidal shape; and

FIGS. 11a-11f are side views showing steps in the fabrication of the semiconductor structure of FIG. 10a, in accordance with the present invention.

### DETAILED DESCRIPTION OF THE INVENTION

The invention includes several semiconductor structures that can operate as solid state light emitting devices and methods of operating and fabricating them. The semiconductor structures employ InGaN light emitting regions which are shaped so that there is a larger amount of indium in one portion of the light emitting region than others. The portion with the higher amount of indium is typically at or near an apex region of the light emitter. Because a larger amount of indium is incorporated in these regions, light of longer wavelength is emitted therefrom. These wavelengths include those in the green, yellow, and red spectrums, as well as the shades of light therebetween. Other portions of the light emitting region include less indium so they emit shorter wavelengths of light, such as those in the blue and violet spectrums, as well as the shades of light therebetween.

In some embodiments, the semiconductor structure can emit one or more wavelengths of light separately and together to provide a desired color of light. For example, the structure can emit red light only or red and green light together. In some embodiments, the structure can also emit polychromatic light, which includes many different colors. For example, the polychromatic light can include red, green, and blue light so that they combine to appear as white light.

It should be noted that other embodiments of the semiconductor structures can include different materials besides nitrides. For example, the semiconductor structure can include III-V semiconductors, such as gallium arsenide, aluminum gallium arsenide, indium phosphide, etc. The semiconductor structure can also include II-VI semiconductors, such as CdZnSSe, ZnCdO, etc.

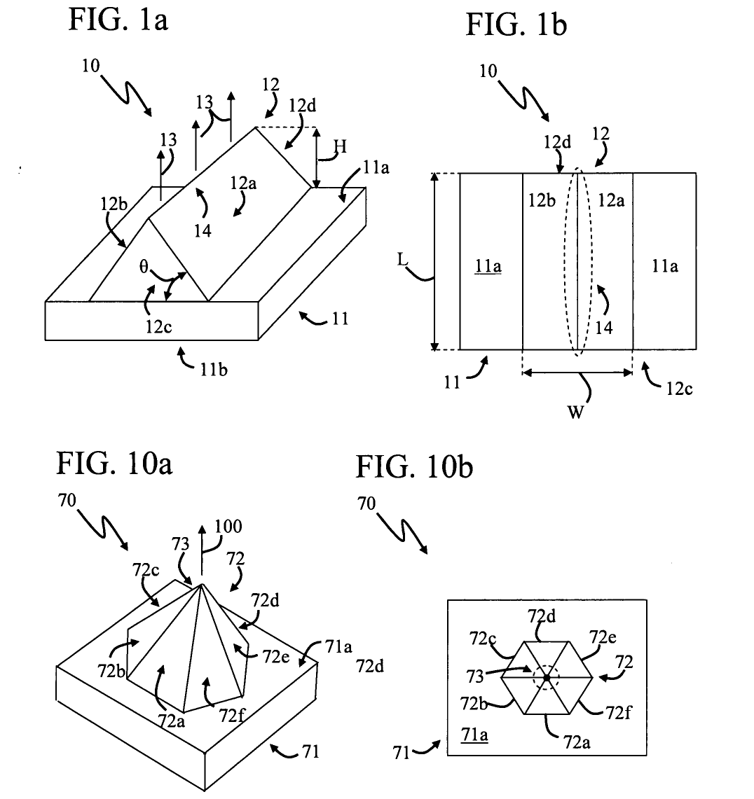

FIGS. 1a and 1b are perspective and top views, respectively, of a semiconductor structure 10, in accordance with the present invention. In this embodiment, structure 10 includes a support structure 11 which carries a light emitter 12 on a surface 11a. Here, light emitter 12 has a triangular prism shape with sloped sidewalls 12a and 12b and opposed sidewalls 12c and 12d. Since light emitter 12 has a triangular prism shape, sloped sidewalls 12a and 12b are rectangular in shape and opposed sidewalls 12c and 12d are triangular in shape.

Opposed sidewalls 12c and 12d extend upwardly from surface 11a and sloped sidewalls 12a and 12b extend between opposed sidewalls 12c and 12d and upwardly at an angle θ relative to surface 11a. Sloped sidewalls 12a and 12b extend away from surface 11a and intersect away from support structure 11 to define an apex region 14. It should be noted that apex region 14 generally includes the intersection of sloped sidewalls 12a and 12b as well as portions of sloped sidewalls 12a and 12b near this intersection (FIG. 1b). Sloped sidewalls 12a and 12b extend a length L and the intersections of sloped sidewalls 12a and 12b with surface 11a are spaced apart from each other by a width W. Apex region 14 is above surface 11a at a height H.

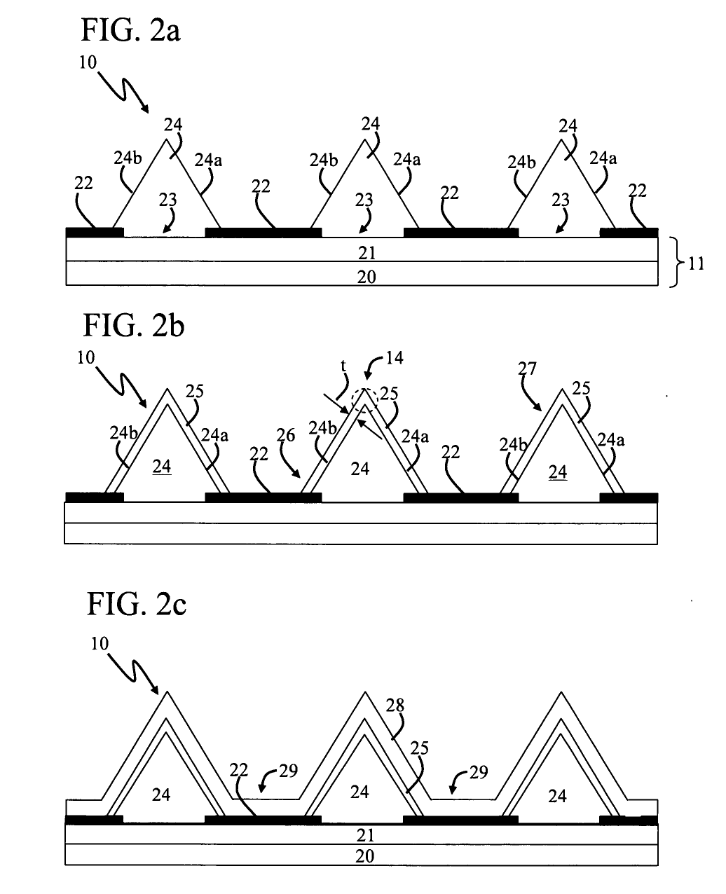

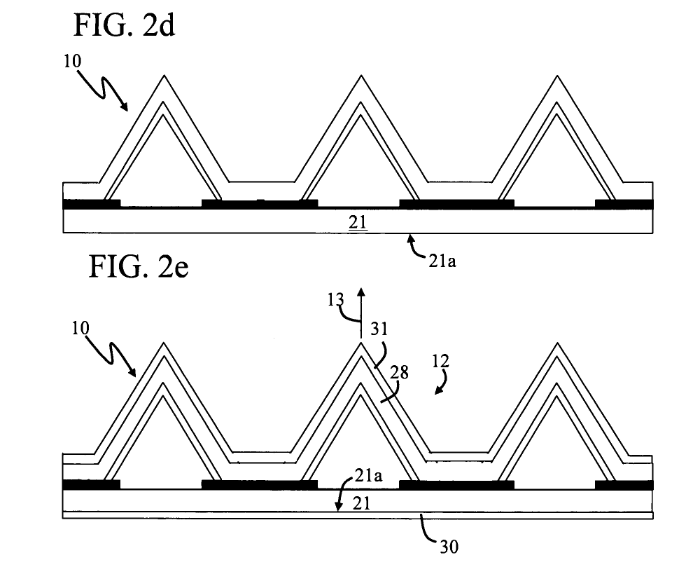

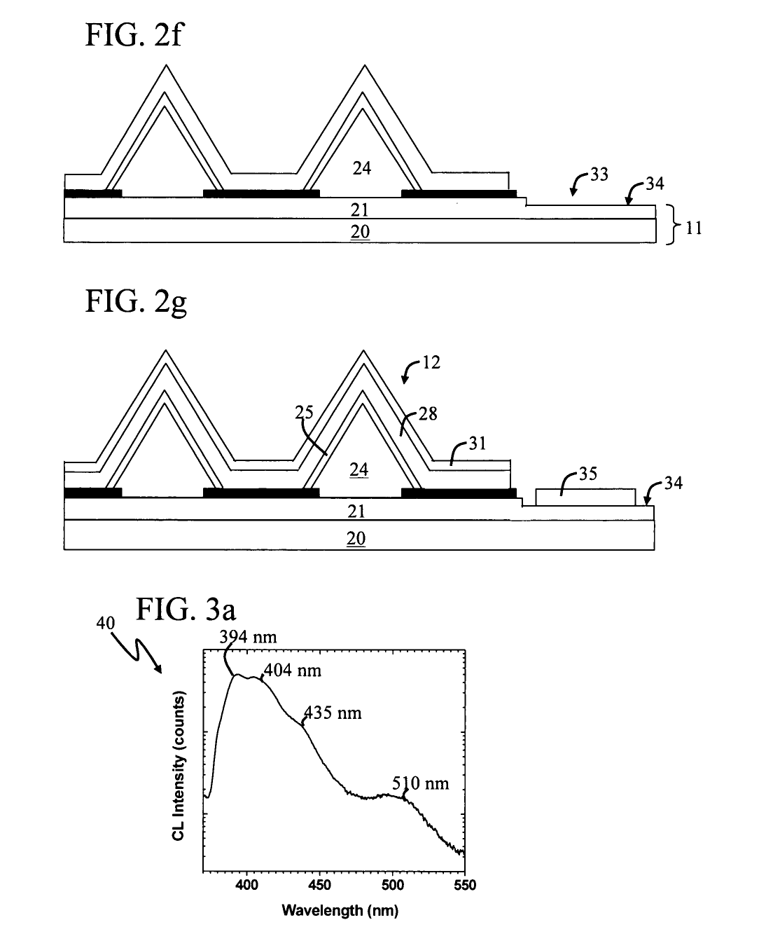

The particular values of W, L, and H can vary over a wide range of dimensions. In this particular example, however, W is about 15 microns (μm), L is about 20 μm and H is about 13 μm, so that angle θ is about 60°. Because of the crystal structure of GaN, angle θ is generally between about 55° to 70°, with a preferred value being between about 58° and 60°. The value of L here corresponds to the length of light emitter 12 after it has been diced, as discussed with FIGS. 2a-2e. However, in other examples, length L can correspond to the length of light emitter 12 before it has been diced.

As shown in FIG. 1b, apex region 14 is generally positioned between the intersection of sidewalls 12a and 12b with surface 11a. In this embodiment, apex region 14 is centrally located and extends along length L of sloped sidewalls 12a and 12b. In operation, light emitter 12 emits light 13 in response to a potential difference between it and support structure 11. Light 13 is emitted from near apex region 14 and away from support structure 11. This feature and others will be discussed in more detail below.

FIGS. 2a-2e are side views showing steps in the fabrication of semiconductor structure 10, in accordance with the present invention. It should be noted that the fabrication of three structures is shown here for simplicity and ease of discussion. After fabrication, the structures are generally diced to provide individual pieces, each of which includes one or more light emitters 12 as shown in FIGS. 1a and 1b. A piece is generally set into a lead frame and, once set, the piece is wire bonded so that electrical signals can be provided to light emitter 12 to control its operation. The electrical signals flow through light emitter 12 and, in response, light emitter 12 emits light.

In FIG. 2a, support structure 11 is provided. In this embodiment, support structure 11 includes a substrate 20 which carries a region 21 of semiconductor material. Here, substrate 14 preferably includes sapphire and region 15 preferably includes GaN for reasons discussed in more detail below. Substrate 20 can include other materials, such as silicon carbide (SiC). In this embodiment, region 21 preferably includes a bulk GaN layer grown on a GaN buffer layer (not shown). In one particular example, the GaN buffer layer is about 30 nanometers (nm) thick and grown on substrate 20 and the bulk GaN layer includes a silicon doped 2.5 μm thick GaN layer. It should be noted that these layers can have other thicknesses and those discussed here are for illustrative purposes. The GaN buffer layer is preferably grown at a low temperature, which is generally between 500° C. and 650° C. for GaN growth.

A mask region 22 is positioned on region 21 and patterned to form openings 23 which extend therethrough to region 21. Mask region 22 can include many different materials, but it preferably includes silicon oxide (SiO). It should be noted that openings 23 are generally rectangular in shape when seen from a top view (FIG. 1b). However, mask region 22 can be patterned in many different geometries having many different dimensions. In this particular example, it preferably is patterned so that openings 23 are about 5 μm to 15 μm wide with a spacing of about 15 μm to 30 μm between the centers of each adjacent opening. It should be noted, however, that other patterns and dimensions can be used for mask region 22 and will generally depend on the particular values for W, L, and/or H.

A base region 24 is grown upwardly from the exposed surface of region 21 through opening 23 using metalorganic chemical vapor deposition (MOCVD). However, other semiconductor deposition methods, such as molecular beam epitaxy, can be used in other examples. Base region 24 is partially grown on mask region 22 using a technique referred to in the art as epitaxial lateral over growth (ELOG).

Using this technique, base region 24 is grown in the shape of a triangular prism (FIG. 1a) having rectangular sloped sidewalls 24a and 24b which intersect away from support structure 11. Some other shapes that base region 24 can be are trapezoidal and cubic. These other shapes can provide variations in thickness t and indium concentration in region 25 to provide different colors of light. As will be discussed in more detail below, these other shapes can provide strain relaxation for the material in apex region 14, which improves its quality.

Region 24 can include many different semiconductor materials, but it preferably includes GaN so that it is lattice matched with the GaN material included in region 21. One reason this is desirable is so that the defect density, as well as the non-radiative recombination, of region 24 is reduced. In this way, emitter 12 will emit more light 13 (FIG. 1a) more efficiently.

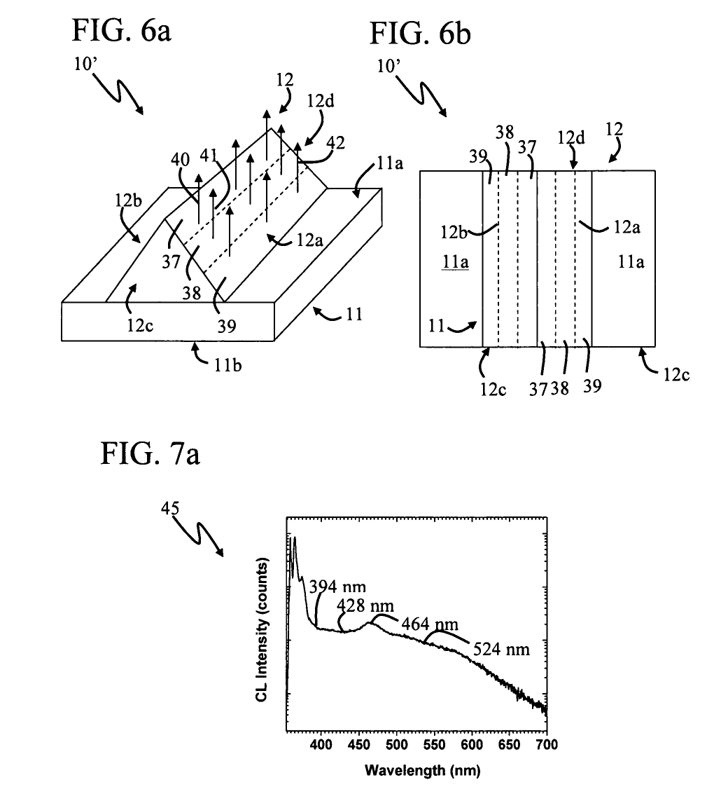

In FIG. 2b, a light emitting region 25 is deposited on base region 24 so that it extends along sidewalls 24a and 24b on and from their intersection with mask region 22. In accordance with the invention, region 25 has a thickness, t, that varies as it extends along sidewalls 24a and 24b. Thickness t is smaller in a portion 26 near support structure 11 and larger in a portion 27 away from support structure 11. Portion 27 is towards apex region 14 (FIG. 1b) and can include all or part of it. Thickness t is generally in a range between 50 nm to 150 nm, but it can have thicknesses outside of this range, as discussed in more detail below with FIGS. 6a and 6b. Thickness t can vary for several different reasons. One reason is because more InGaN is deposited in portion 27 than portion 26 because the angle (i.e. θ) sidewalls 12a and 12b make relative to surface 11a depends upon the temperature at which the growth is performed. Further, light emitting region 25 is deposited at a lower temperature than capping region 24 and the difference in the growth temperature results in a change in the facet angle and a corresponding change in thickness t.

Other reasons include the triangular prism shape of base region 24 and the temperature of the material being deposited in portion 27 is less than the material being deposited in portion 26 so that there is a temperature difference therebetween and a corresponding temperature gradient. The temperature difference between regions 26 and 27 is believed to be about 5° C. to 15° C. and can affect the growth rate of the InGaN material in these regions.

In accordance with the invention, as light emitting region 25 is deposited, its composition also varies as it extends along sidewalls 24a and 24b. The variation in gradient can be continuous in some examples and discontinuous in others. The composition of light emitting region 25 varies for several different reasons, which can be the same or similar to the reasons that thickness t varies. The growth temperature of region 25 affects the amount of indium in the InGaN alloy included therein. Further, there is believed to be a temperature gradient which extends along region 25 and provides a change in its composition. Apex region 14 narrows as it extends away from surface 11a so it cools more rapidly and, consequently, more indium is incorporated therein.

### Possible Additional Claims

As the growth temperature of the indium gallium nitride alloy increases, less indium is incorporated into region 25 and as the growth temperature decreases, more indium is incorporated. The amount of indium (i.e. the value of x) in region 25 can be determined in many different ways, such as by using cathodoluminescence (CL) and comparing the spectrum to that of a reference indium gallium nitride region in a way known in the art. In this determination, a bowing parameter of 1.1 eV and an InN bandgap of 0.8 eV can be used to provide accurate enough comparison results.

In accordance with the invention, apex region 14 extends along the length L of sloped sidewalls 24a and 24b and has a much higher amount of indium then the other portions of region 25. In this way, the InGaN alloy near apex region 14 operates as a quantum wire structure because its bandgap energy is smaller than that of the regions adjacent to it. It is known in the art that it is difficult to incorporate an amount of indium into an indium gallium nitride alloy that is greater than about 0.15 (i.e. x=0.15). This is because the indium gallium nitride material will decompose if the amount of indium is too high (i.e. about or above x=0.15). In accordance with the invention, apex region 14 includes device quality InGaN material with an amount of indium between about 0.15 (i.e. x=0.15) and 0.50 (i.e. x=0.50).

In FIG. 2c, a capping region 28 is deposited on light emitting region 25. In this embodiment, regions 24 and 28 include the same material and have opposite conductivity types. However, the conductivity types of regions 24 and 28 can be reversed in other examples. In this particular example, regions 24 and 28 include n-type and p-type GaN, respectively. Region 25 is preferably doped with silicon (Si) to make it n-type and region 28 is preferably doped with magnesium (Mg) to make it p-type. In this example, region 28 is grown to a thickness so that it extends between adjacent light emitters in a region 29 and covers mask region 22.

After the growth of capping region 28, it is often desirable to thermally anneal it to increase its conductivity, which in this case is p-type. It is believed that the p-type conductivity increases because of the activation of the magnesium dopants and the removal of hydrogen from region 28. The annealing temperature is generally in a range from about 500° C. to 700° C., although temperatures outside of these ranges can be used. In general, the more magnesium is activated and the more hydrogen is removed from region 28 if a higher annealing temperature is used. Further, the less magnesium is activated and the less hydrogen is removed from region 28 if a lower annealing temperature is used.

In FIG. 2d, substrate 20 is removed to expose a surface 21a of region 21. This can be done in many different ways, but is preferably done using laser ablation. In FIG. 2e, a contact region 30 is deposited on surface 21a and a contact region 31 is positioned on capping region 28, so that contacts 30 and 31 are coupled to light emitting region 25. In this embodiment, contact region 31 includes a p-type contact region, such as a layer of nickel on a layer of gold, and contact region 30 includes an n-type contact region, such as a layer of titanium on a layer of aluminum. In operation, light emitter 12 emits light 13 in response to a potential difference between contact regions 30 and 31. This is because a signal flows between contact regions 30 and 31 and through light emitter 12 and light emitting region 25 in response to the potential difference. It should also be noted that, as will be discussed presently, there are other ways of making electrical contact to light emitter 12 so that it can emit light.

FIGS. 2f and 2g are side views of another embodiment showing how structure 10 can be processed to provide electrical contacts to light emitter 12 so that it can emit light. In this embodiment, the processing shown in FIGS. 2f and 2g replaces that shown in FIGS. 2d and FIG. 2e, respectively. In FIG. 2f, region 21, as shown in FIG. 2c, is etched through to form a trench 33 having a bottom surface 34 corresponding to an exposed surface of region 21. In FIG. 2g, a contact region 35 is deposited on surface 34 so that it is coupled to light emitting region 25 through region 21 and contact region 31 is deposited on capping region 28 as described above. Contact region 35 can include the same or similar materials as those included in contact region 30. In operation, light emitter 12 emits light in response to a potential difference between contact regions 31 and 35. This is because a signal flows between contact regions 31 and 35 and through light emitter 12 and light emitting region 25 in response to the potential difference. It should be noted that substrate 20 is not removed from material region 21 as in FIG. 2d, but in other examples it can be.

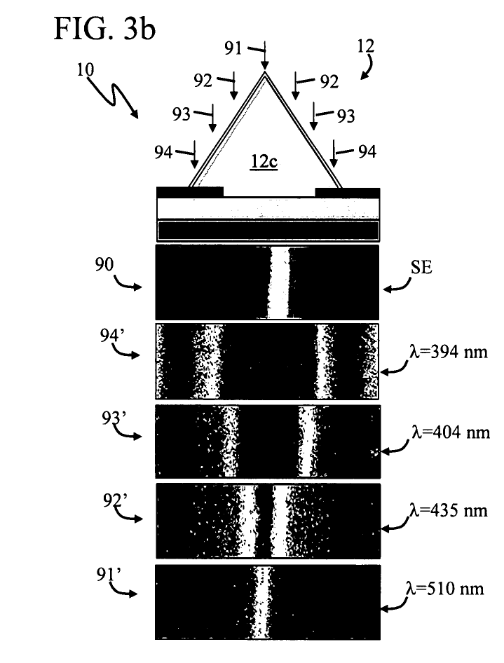

FIG. 3a is a graph 40 of the CL spectrum of light emitting region 25 in structure 10 when grown at a temperature of about 830° C. It should be noted that the light emitted from light emitting region 25 in response to cathodoluminescence is expected to be the same or similar to that emitted when a potential difference is provided between contact regions 30 and 31 (FIG. 2e) or contact regions 31 and 35 (FIG. 2g). The CL spectrum in graph 40, which was measured at a temperature of about 4 Kelvin (K), shows CL emission at about 394 nm, 404 nm, 435 nm, and 510 nm and wavelengths therebetween. As will be discussed in more detail presently, this CL emission arises from different portions of light emitting region 25.

The CL emission at 394 nm is from light emitted by the InGaN material in region 25 where x is about 0.07. The CL emission at 404 nm is from light emitted by the InGaN material in region 25 where x is about 0.11. The CL emission at 435 nm is from light emitted by the InGaN material in region 25 where x is about 0.14. The CL emission at 510 nm is from light emitted by the InGaN material in region 25 where x is about 0.27.

These results reveal several effects, several of which were discussed above. One is that there is a gradient in the amount of indium in light emitting region 25 between portions 26 and 27. In addition, apex region 14 incorporates a significantly higher amount of indium compared to portions of light emitting region 25 away from it, such as in region 26. It is believed that the reason for this is because of the formation during growth of a diffusion layer in light emitting region 25. In the diffusion layer, reactants are transported by diffusion to the growth surface of region 25 so that portion 26 receives less indium than portion 27. Further, portion 26 is typically at a slightly lower temperature than portion 27 because it is away from support structure 11, which makes the incorporation of indium even more difficult. It is believed that these differences result in a gradient in the amount of indium in light emitting region 25.

Another effect is related to the strain relaxation of light emitting region 25 in portion 27. A cubic volume of epitaxially grown InGaN is biaxially strained so that its strain can be reduced through strain relaxation by only a certain amount. However, in portion 27, there is an additional degree of freedom because apex region 14 is narrow. This allows for a larger amount of strain relaxation in apex region 14 and, consequently, the incorporation of more indium therein (i.e. more than x=0.15). This also allows for device quality InGaN material to be grown in apex region 14.

FIG. 3b is a sectional view (FIG. 1a) of semiconductor structure 10 and corresponding images from a top view (FIG. 1b) showing the emission of light at different wavelengths from different portions of region 25 in structure 10. An image 90 is a scanning electron microscopy (SEM) image of the top of structure 10 showing secondary electron (SE) emission therefrom. At positions 91, 92, 93, and 94 on surfaces 12a and 12b, light with wavelength of 510 nm, 435 nm, 404 nm, and 394 nm is emitted, respectively, which correspond to monochromatic CL images 91′, 92′, 93′, and 94′, respectively. These CL images illustrate that different wavelengths of light flow from different portions of region 25 of structure 10 as described in more detail above.

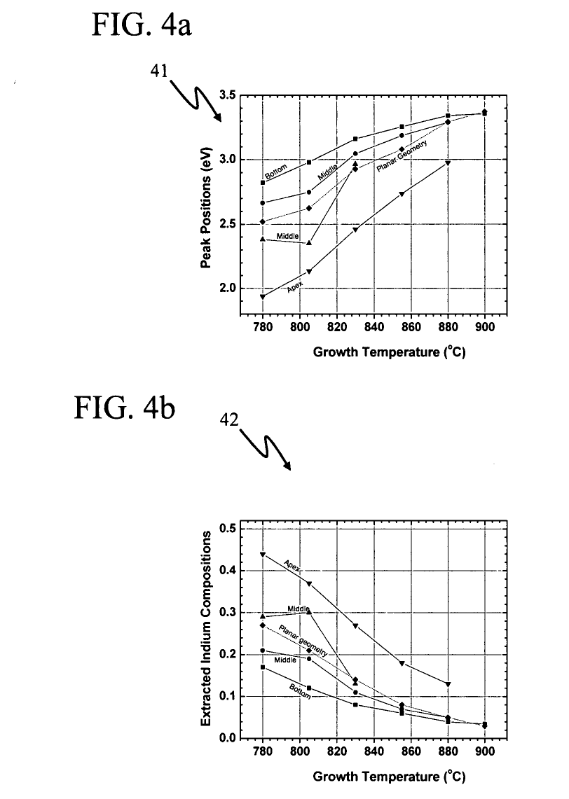

FIG. 4a is a graph 41 showing CL peak positions in electron-volts (eV) versus growth temperature in ° C. for light emitting region 25 in structure 10. It can be seen that the CL peak position changes slightly, at the same temperature, between portion 27 and a region between portions 26 and 27. It can also be seen that the CL peak position changes more significantly, at the same temperature, between portion 26 and a region between portions 26 and 27. Hence, the CL peak position changes more near apex region 14 which indicates that it includes a larger amount of indium than other portions of light emitting region 25.

FIG. 4b is a graph 42 showing the fractional indium composition (x) versus growth temperature in ° C. for light emitting region 25 in structure 10. It can be seen that the indium composition changes slightly, at the same temperature, between portion 27 and a portion of region 25 between portions 26 and 27. It can also be seen that the indium composition changes more significantly, at the same temperature, between portion 26 and the portion of light emitting region 25 between portions 26 and 27. Hence, the amount of indium in light emitting region 25 is much higher near apex region 14 than portions of region 25 away from region 14. In some examples, the amount of indium was found to be as high as 0.50, which is much higher than that found in planar geometry samples. Planar geometry samples occupies a cubic volume of material and do not include an apex region, such as region 14.

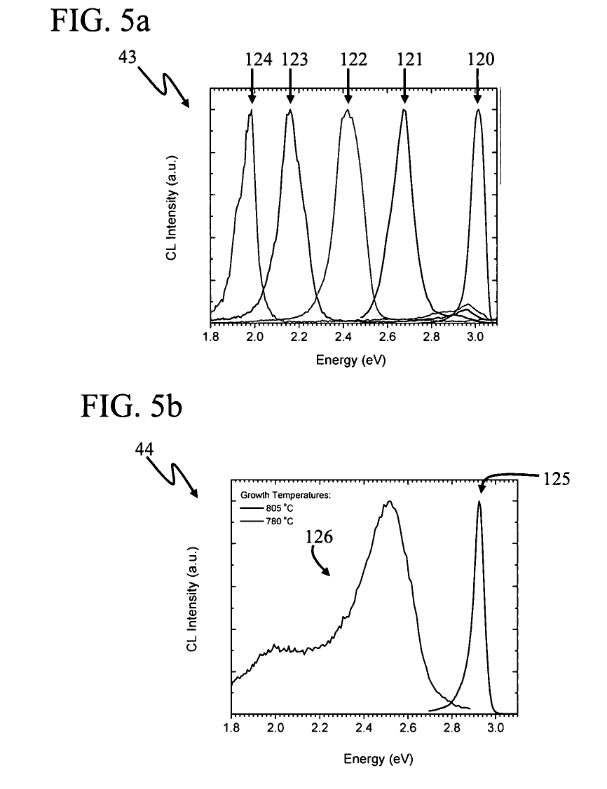

FIG. 5a is a graph 43 showing the CL spectrum from apex region 14 in structure 10 versus the wavelength in nanometers for light emitting region 25 grown at different temperatures. This CL spectrum was measured at a temperature of about 4 K. Samples of structure 10 are provided with region 25 grown at about 880° C., 855° C., 830° C., 805° C., and 780° C. to provide CL peaks 120, 121, 122, 123, and 124, respectively. These CL peaks correspond to violet, blue, green, yellow, and red light, respectively. Further, regions 25 grown at 880° C., 855° C., 830° C., 805° C., and 780° C. include an amount of indium corresponding to about x=0.12, x=0.18, x=0.26, x=0.36, and x=0.44, respectively (FIG. 4b).

Graph 43 shows that the InGaN material included in apex region 14 has a high amount of indium and is still device quality because peaks 120, 121, 122, 123, and 124 are narrower than that from an InGaN sample having a planar geometry, as discussed below. A narrow peak corresponds to fewer defects in the InGaN material and a broader peak corresponds to more defects. This result indicates that it is possible to grow high quality InGaN material regions which have a high indium composition (i.e. x is larger than about 0.15). The material quality is even better when the lattice strain is reduced, as it is in apex region 14.

FIG. 5b is a graph 44 showing the CL intensity verses energy (eV) for an InGaN sample having a planar geometry and a value of x of about 0.13 to 0.14. The CL intensity was measured with the planar InGaN sample at a temperature of about 4 K. Graph 44 includes a peak 125 between about 2.8 eV and 3.0 eV which corresponds to light emitted from the bandedge of the InGaN material. The spectrum between about 1.8 eV and 2.8 eV is much broader than peaks 120-124 in FIG. 5b which indicates that the quality of the InGaN material in the planar InGaN sample is not as good as that in region 14.

FIGS. 6a and 6b are perspective and top views, respectively, of a semiconductor structure 10′, in accordance with the present invention. Structure 10′ is similar to structure 10 described above, however, there are several differences. In accordance with the invention, thickness t of light emitting region 25 is much smaller so that light emitting region 25 operates as a quantum well. Region 25 operates as a quantum well because it is positioned between base region 24 and capping region 28, both of which include higher bandgap material than region 25 so that carriers are confined in it. It should be noted that a single quantum well is shown here for simplicity and ease of discussion, but other embodiments of structure 10′ can include multiple quantum wells. In embodiments with multiple quantum wells, light emitting region 25 includes alternating layers of materials with high and low bandgaps.

In some embodiments, thickness t is made to be less than about 15 nm. In one embodiment, thickness t is in a range between about 1 nm to 5 nm, and preferably about 3 nm. It should be noted that thickness t is generally chosen to provide a desired light emission spectrum. If thickness t is made smaller, then shorter wavelength light is emitted and if thickness t is made larger, then longer wavelength light is emitted. Further, the amount of indium in light emitting region 25 also affects the light emission spectrum. If the amount of indium increases, then the longer wavelength light is emitted and if the amount of indium decreases, then shorter wavelength light is emitted. This is because the depth of the well in the quantum well depends on the amount of indium in light emitting region 25.

An advantage of structure 10′ is that light emitting region 25 emits a spectrum of light which flows through sidewalls 12a and 12b. The wavelength of light varies with position from the intersections of sidewalls 12a and 12b with surface 11a to their intersection with each other. The wavelength is shorter near surface 11a and longer near apex region 14. As an example, sidewall 12a is segmented into regions 37, 38, and 39 which each emit a different wavelength of light. In region 37, light 40 is emitted with a wavelength λ₁, in region 38, light 41 is emitted with a wavelength λ₂, and, in region 39, light 42 is emitted with a wavelength λ₃. In some examples, light 40, 41, and 42 can correspond to light with red, green, and blue wavelengths, respectively. It should be noted, however, that the change in wavelength is generally gradual from one segment to another. The wavelength changes with the indium composition of region 25, as well as its thickness, for reasons discussed above.

It should be noted that in some embodiments, thickness t can be constant so that it is the same in regions 26 and 27, but the amount of indium in region 25 can vary as it extends between region 26 and 14. In this way, region 25 will also provide different colors of light along its length. In other embodiments, thickness t and the amount of indium in regions 26 and 27, as well as regions therebetween, can both be constant so that region 25 will provide different colors of light along its length.

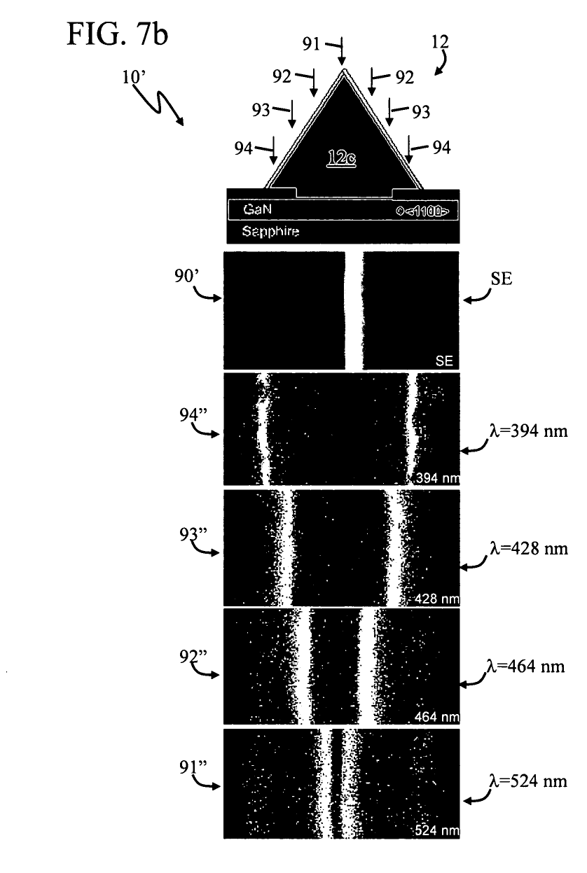

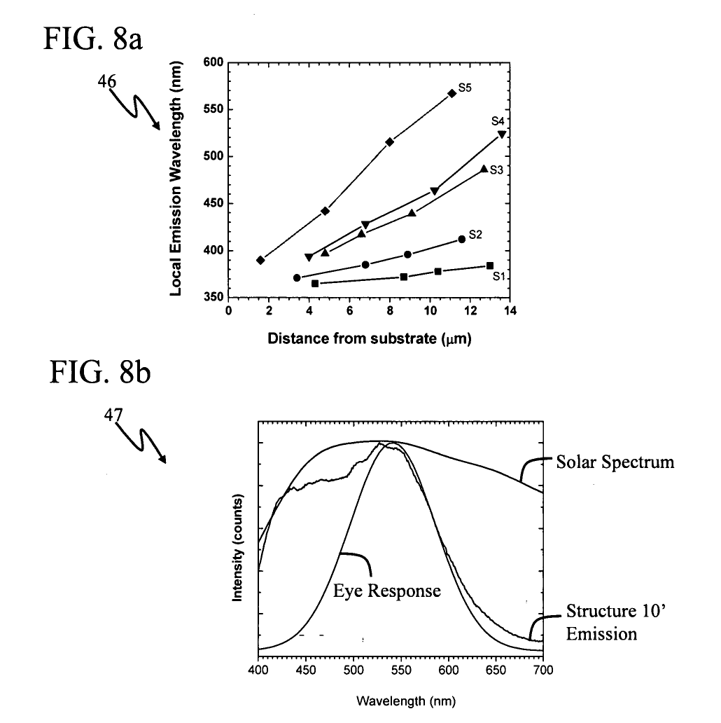

FIG. 7a is a graph 45 showing the CL spectrum versus the wavelength in nanometers for structure 10′. Graph 45 indicates that structure 10′ provides the emission of light over a wider spectrum of wavelengths than that of structure 10 (FIG. 3a). Because of this, the wavelengths of light emitted by structure 10′ combine to appear as whiter light than that provided by structure 10. In other examples, wider and narrower spectra have been obtained, as discussed below with FIG. 8a.

FIG. 7b is a sectional view (FIG. 6a) of semiconductor structure 10′ and corresponding images from a top view (FIG. 6b) showing the emission of light at different wavelengths from different portions of region 25 in structure 10′. An image 90′ is a scanning electron microscopy (SEM) image of the top of structure 10′ showing secondary emission (SE) therefrom. At positions 91, 92, 93, and 94, light with wavelength of 524 nm, 464 nm, 428 nm, and 394 nm is emitted, respectively, which correspond to monochromatic CL images 91″, 92″, 93″, and 94″, respectively. These CL images illustrate that different wavelengths of light flow from different portions of region 25 of structure 10′ as described in more detail above.

FIG. 8a is a graph 46 of the wavelength of light emitted from region 25 versus a distance along region 25 from surface 11 for five different samples, S1, S2, S3, S4, and S5 of structure 10′. These samples where grown at five different temperatures T1, T2, T3, T4, and T5, respectively, where T1>T2>T3>T4>T5. As indicated in graph 46, the samples with a lower amount of indium emit shorter wavelength light and the samples with a higher amount of indium emit longer wavelength. Hence, sample S1 includes the lowest amount of indium because it emits shorter wavelength light and sample S2 has the highest amount of indium because it emits longer wavelength light. Graph 46 also indicates that thickness t increases as region 25 extends away from support structure 11. This is seen because a compositional change in the amount of indium in region 25 will not provide a large change in the emission wavelength, but a change in thickness t will. The change in quantum well thickness with position has been verified by transmission electron microscopy (TEM). The amount of indium will not provide the large change in values for the emission wavelength, but an increase in thickness t will.

FIG. 8b is a graph 47 showing the intensity versus wavelength (nm) for spectrum corresponding to the light emitted from structure 10′. For comparison purposes, the solar spectrum and response of the human eye are also included. Graph 27 shows that structure 10′ emits light at room temperature over a broad spectrum so that it produces white light comparable to the solar spectrum. Further, structure 10′ emits light over a broad spectrum that includes the response of the human eye. This indicates that structure 10′ is useful in solid state lighting and display applications.

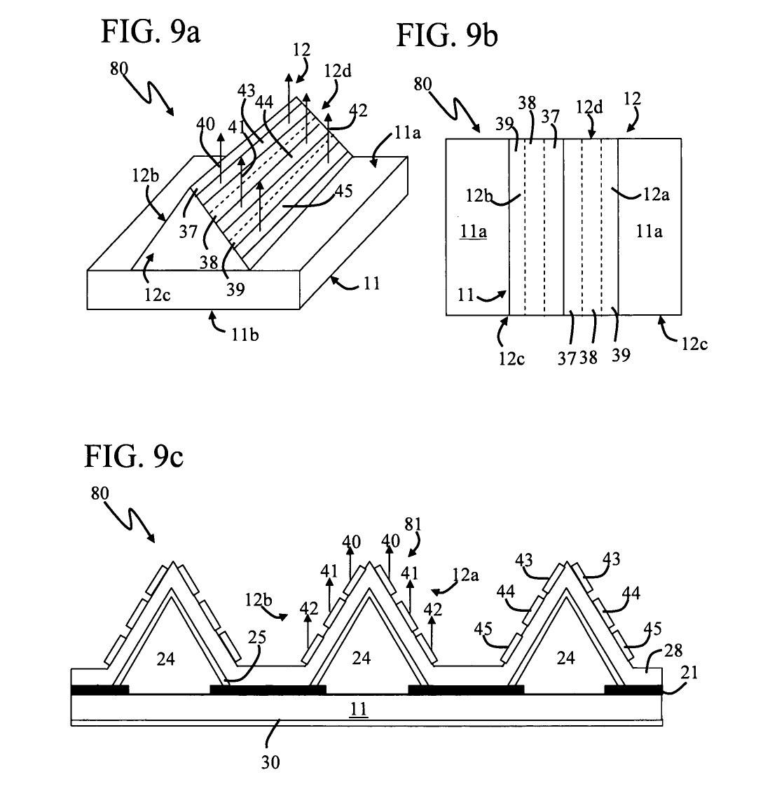

FIGS. 9a, 9b, and 9c show perspective, top, and side views, respectively, of a semiconductor structure 80, in accordance with the present invention. Structure 80 has several advantages with one being that it can emit one or more wavelengths of light. The different wavelengths of light can be emitted together in various combinations to provide a desired spectrum of color. For example, structure 80 can emit red light, green light, or blue light which correspond to the primary colors. It can also emit the various combinations of these colors, such as red and green light, red and blue light, green and blue light, etc. In general, the number of different wavelengths of light that can be emitted depend on the number of electrical contacts positioned on capping region 28 and the composition and/or dimensions of light emitting region 25.

In this embodiment, semiconductor structure 80 is similar to structure 10′ discussed above with FIGS. 6a and 6b. One difference, however, is that contact region 30 has been replaced with multiple contact regions. In particular, structure 80 includes contact regions 43, 44, and 45 positioned on side 12a in regions 37, 38, and 39, respectively. Similarly, structure 80 includes contact regions 43, 44, and 45 positioned on side 12b in regions 37, 38, and 39, respectively (FIG. 9c). It should be noted that the number of different wavelengths of light that can be emitted by region 25 depends substantially on the number of contact regions on sides 12a and 12b. For example, the number of wavelengths that can be emitted increases with the number of contact regions on sides 12a and 12b. Similarly, the number of wavelengths that can be emitted decreases with the number of contact regions on sides 12a and 12b.

In operation, light emitting region 25 emits light 40, 41, and/or 42 in response to a potential difference between contact region 30 and contact regions 43, 44, and/or 45, respectively. In one particular mode of operation, light 40, 41, and 42 are red, green, and blue light, respectively. To emit red light 40, the potential difference between contacts 30 and 43 is about 2.1 volts or more. To emit green light 41, the potential difference between contacts 30 and 44 is about 2.4 volts or more. To emit blue light, the potential difference between contacts 30 and 45 is about 2.7 volts or more. In this way, the color of light emitted by light emitting region 25 depends on the value of the potential difference.

It should be noted that contact regions 43, 44, and 45 are preferably the same or similar to contact region 31 as discussed above. Further, contact regions 43, 44, and 45 are transparent at the wavelengths of light 40, 41, and 42 so that this light can flow therethrough. In this way, semiconductor structure can emit one or more different wavelengths of light individually or together in various combinations.

FIGS. 10a and 10b are perspective and top views, respectively, of a semiconductor structure 70, in accordance with the present invention. In this embodiment, structure 70 includes a support structure 71 which carries a light emitter 72 on a surface 71a. Here, light emitter 72 is pyramidal in shape and includes sloped sidewalls 72a, 72b, 72c, 72d, 72e, and 72f. Sloped sidewalls 72a-72f extend from surface 71a and preferably intersect each other at or near an apex region 73 of emitter 72. As shown in FIG. 10b and from a top view, apex region 73 is centrally located within a hexagon defined by the intersection of sloped sidewalls 72a-72f with surface 71a. Light emitter 72 has six sidewalls for reasons discussed in more detail below. In operation, light emitter 72 emits light 100 in response to a potential difference between support structure 71 and light emitter 72. Light 100 is emitted near apex region 73 and away from support structure 71. The pyramidal base structure can be fabricated by epitaxial lateral overgrowth or by etching the nitrogen face of a GaN as discussed below.

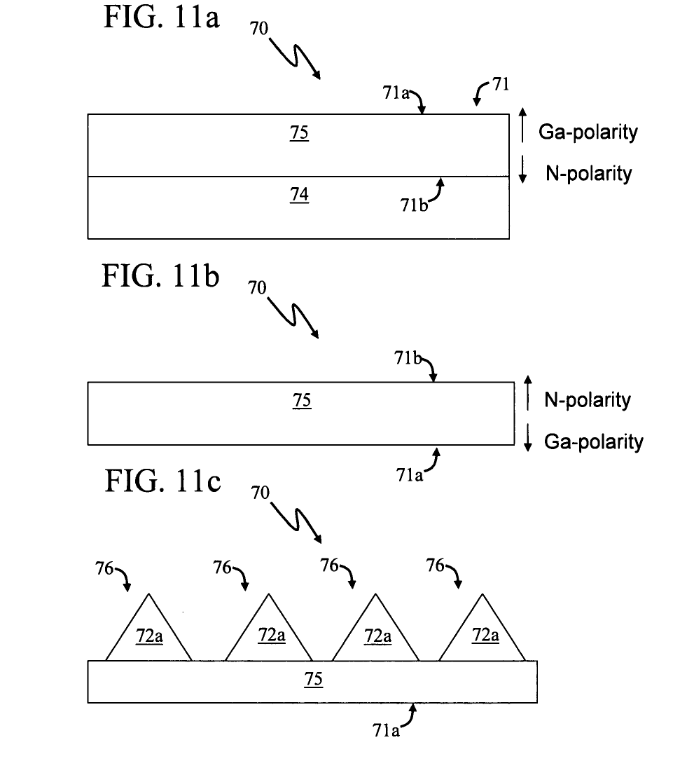

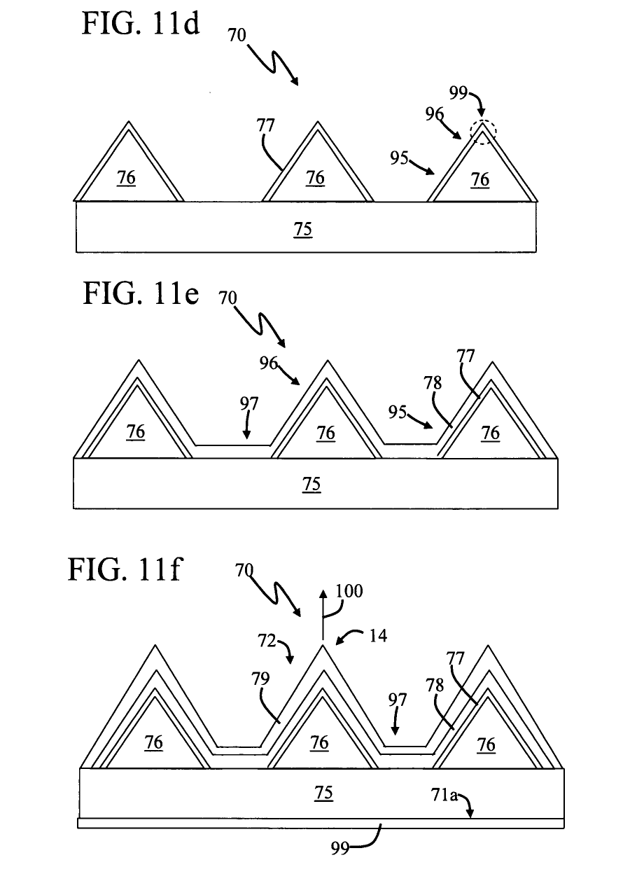

FIGS. 11a-11e are side views showing steps in the fabrication of semiconductor structure 70, in accordance with the present invention. In FIG. 11a, a support structure 71 is provided. In this embodiment, support structure 71 can be the same or similar to support structure 11 describe above. Support structure 71 includes a substrate 74 which carries a region 75 of semiconductor material. Here, substrate 74 preferably includes sapphire and region 75 preferably includes gallium nitride. In accordance with the invention, region 75 includes GaN which is grown so that its surface 71b adjacent to support substrate 74 is nitrogen terminated and its surface 71a away from substrate 74 is gallium terminated. In this way, region 75 has a nitrogen polarity directed towards substrate 74 and a gallium polarity directed away from substrate 74. In FIG. 11b, substrate 74 is removed from region 75 to expose surface 71b. This can be done in many different ways, but is preferably done using laser ablation.

In FIG. 11c, region 75 is etched through surface 71b towards surface 71a to form a plurality of pyramidal shaped base regions 76. Region 75 can be etched in many different ways to form base regions 76 so they have pyramidal shapes. A preferred etching method is to etch region 75 with potassium hydroxide (KOH) because the KOH will etch the GaN included therein along its (0001) surface to form the pyramidal shapes of regions 76. The pyramidal shapes have six triangularly shaped sloped sidewalls (i.e. sidewalls 72a-72f) because the GaN in region 75 is grown with a hexagonal lattice structure. The etching is preferably done with the KOH being at an elevated temperature. This increases the rate at which KOH etches GaN.

In FIG. 11d, a light emitting region 77 is deposited on base region 76 so that it extends along sidewalls 72a-72f (FIG. 10a). Region 77 has a thickness, t, that varies as it extends along sidewalls 72a-72f in a manner similar to that of light emitting region 25. Thickness t is larger in a region 95 near region 75 and smaller in a region 96 near an apex region 99. Thickness t is generally in a range between 50 nm to 150 nm, but it can have thicknesses outside of this range, such as those thicknesses discussed with FIGS. 6a and 6b.

In accordance with the invention, as region 77 is deposited, a temperature gradient between regions 95 and 96 provides region 95 with less indium than region 96. In this way, there is a gradient in the amount of indium included in region 77. At a higher growth temperature, less indium is incorporated into region 77 and at a lower growth temperature, more indium is incorporated. The amount of indium in region 77 can be determined in many different ways, as discussed above. A greater degree of strain relaxation in region 77 is expected near apex region 99. The strain relaxation is believed to be more than that near apex region 14 of structures 10 and 10′ because apex region 99 is narrower in three dimensions instead of just two as in a structure having a triangular prism shape.

In FIG. 11e, a capping region 78 is deposited on light emitting region 77. In this embodiment, regions 76 and 78 can be the same or similar to regions 24 and 28, respectively. Region 78 is preferably grown to a thickness so that it extends between adjacent light emitters in a region 97. In FIG. 11f, a contact region 99 is deposited on surface 71a and a contact region 79 is deposited on capping region 78 to form light emitting device 72. Contact regions 79 and 99 can be the same or similar to corresponding contact regions 30 and 31 discussed above. In operation, light emitting device 72 emits light 100 from apex region 14 in response to a potential difference between contact regions 79 and 99.

Hence, several embodiments of a semiconductor structure are disclosed which can emit one or more wavelengths of light more efficiently than previous light emitters. Light at longer wavelengths can also be emitted because these structures provide for the incorporation of more indium to their light emitting regions. In some embodiments of the structures, a plurality of wavelengths of light are emitted so that the wavelengths combine to appear as white light. This is done without using down conversion material, as is used in most of the prior art.

The embodiments of the invention described herein are exemplary and numerous modifications, variations and rearrangements can be readily envisioned to achieve substantially equivalent results, all of which are intended to be embraced within the spirit and scope of the invention as defined in the appended claims.

1. A semiconductor structure (10, 10′, 70, 80), comprising:
a light emitter (12, 72) carried by a support structure (11), the light emitter (12, 72) including a base region (24, 76) with a sloped sidewall (12a, 12b) and a light emitting region (25, 77) positioned thereon, the light emitting region (25, 77) including a nitride semiconductor alloy having a composition that is different in a first region (26, 95) near the support structure (11) compared to a second region (27, 96) away from the support structure (11).

2. The structure of claim 1, wherein the nitride semiconductor alloy includes indium gallium nitride with an amount of indium in the first region (26, 95) being less then an amount of indium in the second region (27, 96).

3. The structure of claim 1, wherein the strain in the semiconductor alloy is greater in the first region (26, 95) than in the second region (27, 96).

4. The structure of claim 1, wherein the base region (24, 76) and sloped sidewall (12a, 12b) are pyramidal and triangular in shape, respectively.

5. The structure of claim 4, wherein the nitride semiconductor alloy near the apex (14) of the light emitter (12, 72) operates as a quantum dot structure.

6. The structure of claim 1, wherein the base region (24, 76) has a triangular prism shape and the sloped sidewall (12a, 12b) has a rectangular shape.

7. The structure of claim 6, wherein the nitride semiconductor alloy near the apex (14) of the base region (24, 76) operates as a quantum wire structure.

8. The structure of claim 6, further including a capping region (28, 78) carried by the light emitting region (25, 77) so that it operates as a quantum well structure.

9. A light emitter (12, 72), comprising:
a base region (24, 76) having a plurality of sloped sidewalls (12a, 12b) which intersect; and
a light emitting region (25, 77) positioned on the sloped sidewalls (12a, 12b), the light emitting region (25, 77) having a thickness that is different in a first region (27, 96) near the intersection of the sloped sidewalls compared to a second region (26, 95) away from the intersection.

10. The emitter of claim 9, wherein the light emitting region (25, 77) includes an indium gallium nitride semiconductor alloy having a composition of indium that is different in the first region (27, 96) compared to the second region (26, 95).

11. The emitter of claim 9, wherein the light emitting region (25, 77) emits a desired color of light in response to a signal flowing therethrough.

12. The emitter of claim 9, further including a capping region (28, 78) carried by the light emitting region (25, 77), the base (24, 76) and capping (28, 78) regions having opposite conductivity types.

13. The emitter of claim 12, further including a first contact (30, 35, 99) coupled to the base region (24, 76) and a second contact (31, 40, 41, 42, 79) coupled to the capping region (28, 78), the light emitting region (25, 77) emitting one or more desired wavelengths of light in response to a potential difference between the first (30, 35, 99) and second contacts (31, 40, 41, 42, 79).

14. The emitter of claim 12, further including a first contact (30, 35, 99) coupled to the base region (24, 76) and a plurality of second contacts (40, 41, 42) coupled to the capping region (28, 78), the light emitting region (25, 77) emitting a desired color of light in response to a potential difference between the first contact (30, 35, 99) and at least one of the second contacts (40, 41, 42).

15. The emitter of claim 14, wherein the color of light emitted by the light emitting region depends on the value of the potential difference.

16. A method of forming a light emitter (12, 72), comprising:
providing a base region (24, 76) having a plurality of sloped sidewalls (12a, 12b) which intersect; and
positioning a light emitting region (25, 77) on the sloped sidewalls (12a, 12b), the light emitting region (25, 77) including an indium nitride semiconductor alloy having a composition of indium that is different in a first region (27, 96) near the intersection of the sloped sidewalls compared to a second region (26, 95) away from the intersection.

17. The method of claim 16, wherein the strain in the semiconductor alloy is greater in the first region (27, 96) than in the second region (26, 95).

18. The method of claim 16, wherein the thickness of the light emitting region (25, 77) is greater in the first region (27, 96) than in the second region (26, 95).

19. The method of claim 16, wherein the base region (24, 76) and sloped sidewall (12a, 12b) are pyramidal and triangular in shape, respectively.

20. The method of claim 16, wherein the base region (24, 76) has a triangular prism shape and the sloped sidewall (12a, 12b) has a rectangular shape.

21. The method of claim 20, wherein the light emitting region (25, 77) has a thickness chosen so that it operates as a quantum well.
